(19) United States
(12) Patent Application Publication
(10) Pub. No.: US 2026/0214920 A1
(43) Pub. Date: Jul. 23, 2026

(54) SEMICONDUCTOR DEVICE

(71) Applicant: Samsung Electronics Co., Ltd., Suwon-si (KR)

(72) Inventors: Kyunghwan Lee, Suwon-si (KR); Daewon Ha, Suwon-si (KR)

(21) Appl. No.: 19/279,858

(22) Filed: Jul. 24, 2025

(30) Foreign Application Priority Data
Jan. 21, 2025 (KR) 10-2025-0009031

(51) Int. Cl. H10D 1/68; G11C 5/06; H10B 53/10; H10B 53/20; H10D 64/68

(52) U.S. Cl. CPC H10D 1/716; G11C 5/063; H10B 53/10; H10B 53/20; H10D 1/696; H10D 64/689

(57) ABSTRACT

A semiconductor device includes a substrate, a bit line and a word line extending in a direction intersecting each other on the substrate, a semiconductor pattern connected to the bit line and adjacent to the word line, and a plurality of data storages connected to the semiconductor pattern, wherein the data storage includes a first electrode positioned in a direction that is perpendicular to the substrate, a plurality of second electrodes positioned in a direction that is parallel to the substrate, and a dielectric layer disposed between the first electrode and the second electrode, a planar area of the first electrode in a direction that is parallel to the substrate increases as it moves away from the substrate, and a thickness of each of the second electrodes in a direction that is perpendicular to the substrate increases as it gets closer to the substrate.

### CROSS-REFERENCE TO RELATED APPLICATION

This application claims priority to and the benefit of Korean Patent Application No. 10-2025-0009031 filed with the Korean Intellectual Property Office on Jan. 21, 2025, the entire contents of which are incorporated herein by reference.

### BACKGROUND

Technology is being developed to increase an integration density of semiconductor device. In the case of a two-dimensional semiconductor device, an integration level is mainly determined by an area occupied by a unit memory cell, and this aspect of integration level may be affected by a level of fine pattern formation technology.

However, the fine pattern formation technology requires expensive equipment, so the integration of two-dimensional semiconductor device is increasing, but is still limited. Accordingly, three-dimensional semiconductor memory devices including three-dimensionally arranged memory cells are being proposed.

### SUMMARY

Some aspects of the present disclosure provide semiconductor devices having improved sensing margins and operating characteristics.

Some aspects of the present disclosure provide a semiconductor device including: a substrate, a bit line and a word line extending in a direction intersecting each other on the substrate, a semiconductor pattern connected to the bit line and adjacent to the word line, and a plurality of data storages connected to the semiconductor pattern, wherein the data storage includes a first electrode positioned in a direction that is perpendicular to the substrate, a plurality of second electrodes positioned in a direction that is parallel to the substrate, and a dielectric layer disposed between the first electrode and the second electrode, wherein a planar area of the first electrode in a direction that is parallel to the substrate increases as it moves away from the substrate, and a thickness of each of the second electrodes in a direction that is perpendicular to the substrate increases as it gets closer to the substrate.

Some aspects of the present disclosure provide a semiconductor device including a substrate, a bit line and a word line extending in a direction intersecting each other on the substrate, a semiconductor pattern connected to the bit line and adjacent to the word line, and a plurality of data storages connected to the semiconductor pattern, wherein the data storage includes a first electrode positioned in a direction that is perpendicular to the substrate, a plurality of second electrodes positioned in a direction that is parallel to the substrate, and a dielectric layer disposed between the first electrode and the second electrode, a planar area of the first electrode in a direction that is parallel to the substrate increases as it moves away from the substrate, the second electrodes include a first group having a first thickness and a second group having a second thickness, the first thickness is greater than the second thickness, and the first group is positioned closer to the substrate than the second group.

Some aspects of the present disclosure provide a semiconductor device including a substrate, a bit line and a word line extending in a direction intersecting each other on the substrate, a semiconductor pattern connected to the bit line and adjacent to the word line, and a plurality of data storages connected to the semiconductor pattern, wherein the data storage includes a first electrode positioned in a direction that is perpendicular to the substrate, a plurality of second electrodes positioned in a direction that is parallel to the substrate, and a dielectric layer disposed between the first electrode and the second electrode, a planar area in a direction that is parallel to the substrate at a lower surface of the first electrode that is closest to the substrate is smaller than a planar area in a direction that is parallel to the substrate at an upper surface that is farthest from the substrate, and a thickness of the second electrode, among the plurality of second electrodes, that is positioned closest to the substrate in a direction perpendicular to the substrate, is greater than a thickness of the second electrode, among the second electrodes, that is positioned farthest from the substrate in a direction perpendicular to the substrate.

Some aspects of the present disclosure provide a manufacturing method for a semiconductor device, including forming a bit line and a word line extending in directions intersecting each other on a substrate, and a semiconductor pattern connected to the bit line and adjacent to the word line; alternately stacking a sacrificial layer and an interlayer insulating layer on the substrate; forming a hole by etching the sacrificial layer and the interlayer insulating layer; and forming a second electrode, a dielectric layer, and a first electrode inside the hole, wherein the first electrode is formed in a direction perpendicular to the substrate, the second electrode is formed in a direction parallel to the substrate in a space where the sacrificial layer was positioned, and a thickness of the sacrificial layer in the direction perpendicular to the substrate increases as it gets closer to the substrate.

A thickness of the second electrode in a direction perpendicular to the substrate may increase as it gets closer to the substrate.

In the forming of the hole by etching the sacrificial layer and the interlayer insulating layer, a planar area of the hole in a direction parallel to the substrate may decrease as it gets closer to the substrate.

A diameter of a lower surface of the first electrode close to the substrate may be smaller than a diameter of an upper surface of the first electrode farthest from the substrate.

The sacrificial layer and the interlayer insulating layer may include different materials.

After the forming the hole by etching the sacrificial layer and the interlayer insulating layer, it may further include selectively etching the sacrificial layer.

The first electrode may include a first portion positioned in a direction that is perpendicular to the substrate and a second portion protruding from the first portion in a direction that is parallel to the substrate.

The first electrode and the second electrode may include metals having different work functions.

The second electrodes may surround the first electrode in a plan view.

The second electrode may include a portion that is separated therefrom without surrounding the first electrode in a plan view.

Accordingly, semiconductor devices having improved sensing margin and operational characteristics may be provided.

### BRIEF DESCRIPTION OF THE DRAWINGS

FIG. 1 is a top plan view of an example of a semiconductor device.

FIG. 2 is a cross-sectional view taken along a line II-II′ of FIG. 1.

FIG. 3 and FIG. 4 are diagrams illustrating capacitors in a semiconductor device where a thickness of a second electrode is uniform.

FIG. 5 and FIG. 6 are diagrams illustrating capacitors in a semiconductor device where a thickness of a second electrode varies by region.

FIG. 7 is a cross-sectional view of an example of a semiconductor device taken along a line II-II′ of FIG. 1.

FIG. 8 is a cross-sectional view illustrating an example of a semiconductor device.

FIG. 9 is a cross-sectional view illustrating an example of a semiconductor device.

FIG. 10 is a cross-sectional view illustrating an example of a semiconductor device.

FIG. 11 is a schematic cross-sectional diagram showing a first electrode, a dielectric layer, and a second electrode of an example of a capacitor.

FIG. 12 is a cross-sectional diagram corresponding to FIG. 11 for another example of a semiconductor device.

FIG. 13 is a cross-sectional diagram corresponding to FIG. 11 for another example of a semiconductor device.

FIG. 14 is a plan view corresponding to FIG. 1 for another example of a semiconductor device.

FIG. 15 is a plan view corresponding to FIG. 1 for another example of a semiconductor device.

FIG. 16 to FIG. 45 are process diagrams showing an example of a manufacturing process for a semiconductor device.

### DETAILED DESCRIPTION

The present disclosure will be described more fully hereinafter with reference to the accompanying drawings, in which certain examples are shown. As those skilled in the art would realize, the described examples may be modified in various different ways without departing from the spirit or scope of the present disclosure.

For clarity of description, some parts that are less relevant to the description are omitted, and like numerals refer to like or similar components throughout the specification.

Further, since sizes and thicknesses of constituent members shown in the accompanying drawings are arbitrarily given for better understanding and ease of description, the present disclosure is not limited to the illustrated sizes and thicknesses. For example, in the drawings, the thicknesses of layers, areas, films, panels, regions, etc., may be exaggerated for clarity.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the words “on” or “above” refer to a relative, and do not necessarily mean positioned on the upper side of an element based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

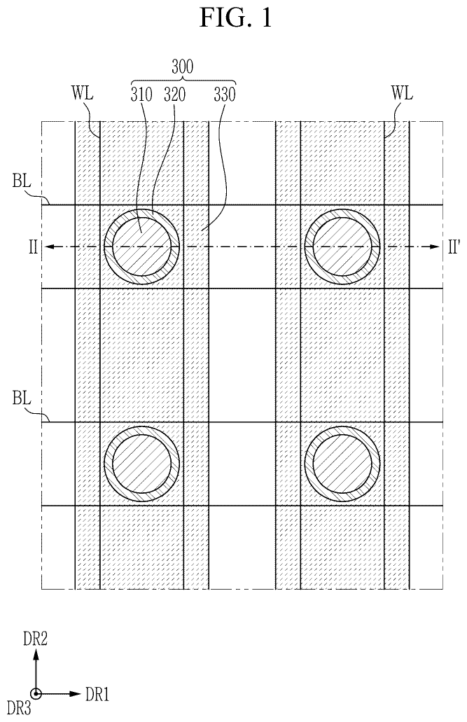

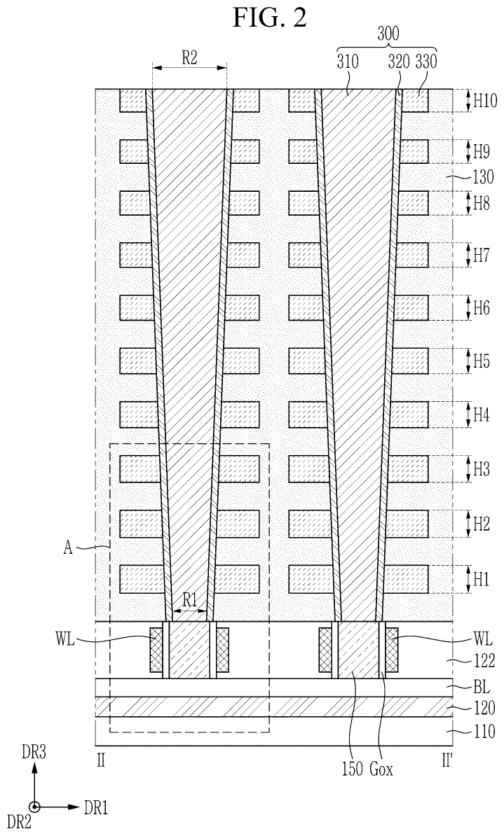

FIG. 1 illustrates a top plan view of an example of a semiconductor device. FIG. 2 illustrates a cross-sectional view taken along a line II-II′ of FIG. 1.

Referring to FIGS. 1 and 2, a semiconductor device may include a substrate 110, a bit line BL and a word line WL extending in directions intersecting each other on the substrate 110, a semiconductor pattern 150 connected to the bit line BL and adjacent to the word line WL, and a plurality of capacitors 300 connected to the semiconductor pattern 150. The capacitors 300 may function as a data storage.

The semiconductor device may include a plurality of memory cells. Each of the memory cells may include the semiconductor pattern 150, the bit line BL connected to the semiconductor pattern 150, the word line WL adjacent to the semiconductor pattern 150, and the data storages (capacitors 300) connected to the semiconductor pattern 150. The memory cells may be stacked in a third direction DR3 perpendicular to an upper surface of the substrate 110. The memory cells may be arranged along a first direction DR1 and a second direction DR2 parallel to the upper surface of the substrate 110 within a same layer. For example, the semiconductor device may include memory cells that are three-dimensionally stacked.

Each of the memory cells may include a transistor and a plurality of data storages connected to the transistor. The semiconductor device may be a dynamic random access memory (DRAM), a ferroelectric RAM (FeRAM), or an antiferroelectric RAM (AFeRAM) depending on a material of a dielectric layer included in a data storage. Although FIGS. 1 and 2 illustrate one transistor and a plurality of capacitors connected to the one transistor, the semiconductor device is not limited to this configuration and may, for example, include two transistors and a plurality of capacitors connected to the two transistors.

The substrate 110 may include a semiconductor material. For example, the substrate 110 may include a group IV semiconductor, a group III-V compound semiconductor, a group II-VI compound semiconductor, and the like. For example, the substrate 110 may include a semiconductor such as Si or Ge, or a compound semiconductor such as SiGe, SiC, GaAs, InAs, or InP. For example, the substrate 110 may be a monocrystalline epitaxial layer grown on a monocrystalline silicon substrate. However, a material included in the substrate 110 is not limited thereto, and may be variously changed.

A first insulating layer 120 may be positioned on the substrate 110. The first insulating layer 120 may be positioned on an upper surface of the substrate 110. The first insulating layer 120 may cover the upper surface of the substrate 110.

The first insulating layer 120 may include an insulating material. For example, the first insulating layer 120 may include a silicon oxide (SiOₓ), a silicon nitride (SiNₓ), a silicon oxynitride (SiONₓ), or a combination thereof, but the present disclosure is not limited thereto.

The bit line BL may be positioned on the first insulating layer 120. Referring to FIG. 1 and FIG. 2 together, a plurality of bit lines BL may be extended and positioned along the first direction DR1. Additionally, the bit lines BL may be arranged spaced apart from each other in the second direction DR2.

The bit line BL may include a conductive material. The bit line BL may include, e.g., a doped semiconductor material, a conductive metal nitride, a metal, a metal-semiconductor compound, or a combination thereof, but the present disclosure is not limited thereto.

The semiconductor pattern 150 may be positioned in contact with the bit line BL. Referring to FIG. 2, the semiconductor pattern 150 may be positioned to overlap the first electrode 310 in the third direction DR3. Accordingly, the semiconductor pattern 150 may be positioned at a lower portion of the first electrode 310. A plurality of semiconductor patterns 150 may be positioned in multiple positions spaced apart from each other in the first direction DR1 and the second direction DR2. Referring to FIG. 1 and FIG. 2 together, the semiconductor pattern 150 may be positioned at a portion or position (e.g., position in the first and second directions DR1 and DR2) where the word line WL and the bit line BL intersect. As illustrated in FIG. 2, a first end of the semiconductor pattern 150 may be in contact with the bit line BL.

The semiconductor patterns 150 may include a semiconductor material. For example, the semiconductor patterns 150 may include silicon, germanium, or silicon-germanium. For example, the semiconductor patterns 150 may include monocrystalline silicon or polycrystalline silicon. However, the material(s) are not limited thereto. For example, the semiconductor pattern 150 may include an oxide semiconductor material such as an indium gallium zinc oxide (IGZO). For example, the semiconductor pattern 150 may include an oxide semiconductor material such as IGZO, Sn-IGZO, IWO, CuS₂, WSe₂, IZO, ZTO, YZO, or MIZO. As another example, the semiconductor pattern 150 may include a two-dimensional semiconductor material. For example, the semiconductor pattern 150 may include a two-dimensional semiconductor material such as MoS₂, MoSe₂, or WS₂.

Referring to FIG. 2, the word line WL may be positioned such that it is insulated from the bit line BL. A second insulating layer 122 may be positioned between the bit line BL and the word line WL. The second insulating layer 122 may include an insulating material. For example, the second insulating layer 122 may include a silicon oxide (SiOₓ), a silicon nitride (SiNₓ), a silicon oxynitride (SiONₓ), or a combination thereof, but the present disclosure is not limited thereto.

In some implementations, the semiconductor device may include a plurality of word lines WL. Referring to FIG. 1 and FIG. 2, the word lines WL may be extended and positioned along the second direction DR2. Additionally, the word lines WL may be arranged spaced apart from each other in the first direction DR1.

The word line WL may be adjacent to the semiconductor pattern 150. Referring to FIG. 1 and FIG. 2, the word line WL may be positioned to surround the semiconductor pattern 150.

The semiconductor device may include a gate insulating layer Gox positioned between the word line WL and the semiconductor pattern 150. The word line WL may be separated from the semiconductor pattern 150 by the gate insulating layer Gox.

The word line WL may include a conductive material. The word line WL may include, e.g., a doped semiconductor material, a conductive metal nitride, a metal, a metal-semiconductor compound, or a combination thereof, but the present disclosure is not limited thereto.

The gate insulating layer Gox may include at least one of a high dielectric constant material, a silicon oxide, a silicon nitride, or a silicon nitride. The high dielectric constant material may include, e.g., at least one of a hafnium oxide, a hafnium silicon oxide, a lanthanum oxide, a zirconium oxide, a zirconium silicon oxide, a tantalum oxide, a titanium oxide, a barium strontium titanium oxide, a barium titanium oxide, a strontium titanium oxide, a lithium oxide, an aluminum oxide, a lead scandium tantalum oxide, or a lead zinc niobate.

The second insulating layer 122 may be positioned on the word line WL. In FIG. 2, an insulating layer positioned between the word line WL and the bit line BL and on the word line WL is illustrated as the single second insulating layer 122, but this is merely an example, and an insulating layer positioned between the word line WL and the bit line BL and an insulating layer positioned on the word line WL may be different.

Referring to FIGS. 1 and 2, the first electrode 310 may be positioned to overlap the semiconductor pattern 150 (e.g., along the third direction DR3). The first electrode 310 may be positioned to extend in the third direction DR3. As shown in FIGS. 1 and 2, the first electrode 310 may have a cylindrical shape extending in the third direction DR3. However, this shape of the first electrode 310 is merely an example, and the present disclosure is not limited thereto. In some implementations, a planar cross-section of the first electrode 310 may be quadrangular, and the first electrode 310 may have a quadrangular pillar shape. Additionally, in some implementations, the first electrode 310 may include a vertical portion extending in the third direction DR3 and an extension extending in a direction intersecting the vertical portion. Shapes of other examples of first electrodes 310 will be described later.

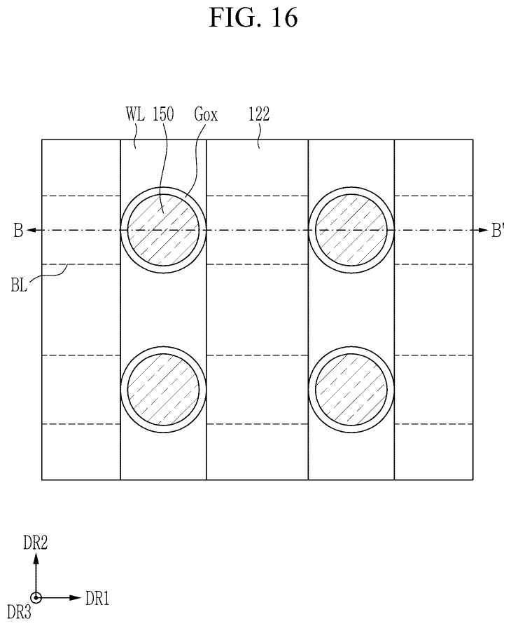

As illustrated in FIG. 2, the first electrode 310 may be positioned to extend in the third direction DR3. As will be described with respect to FIGS. 16 to 45, during the process of forming the first electrode 310, a hole may be formed in the third direction DR3 and then the hole may be filled with a conductive material to form the first electrode 310. Upper and lower diameters of the hole formed at this time may be different. This is a shape derived from an etching process to form a hole. Accordingly, a diameter R2 at an uppermost portion of the first electrode 310 and a diameter R1 at a lowermost portion of the first electrode 310 may also be different. As illustrated in FIG. 1, the diameter R2 at the uppermost portion of the first electrode 310 may be larger than the diameter R1 at the lowermost portion of the first electrode 310. For example, a diameter of the first electrode 310 in a direction parallel to the substrate 110 may vary by region. As shown in FIG. 2, the diameter of the first electrode 310 in the direction parallel to the substrate 110 may gradually increase as it moves away from the substrate 110. In some implementations, based at least on the diameter of the first electrode 310 varying by layer, a capacitance of a capacitor including the first electrode 310 may also vary by region, as will be described later.

A first end of the first electrode 310 may be in contact with the semiconductor pattern 150. The first electrode 310 may include a conductive material. The first electrode 310 may include, e.g., at least one of a metal material, a conductive metal nitride, or a doped semiconductor material.

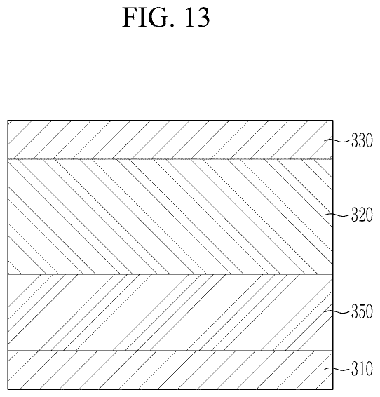

Referring to FIG. 2, a dielectric layer 320 may be positioned along a periphery of the first electrode 310. Referring to FIG. 1 and FIG. 2 together, the dielectric layer 320 may be positioned to surround the first electrode 310. The dielectric layer 320 may include at least one of a high-dielectric material, a ferroelectric material, or an antiferroelectric material. In some implementations, the high dielectric constant material may include, e.g., at least one of a hafnium oxide, a hafnium silicon oxide, a lanthanum oxide, a zirconium oxide, a zirconium silicon oxide, a tantalum oxide, a titanium oxide, a barium strontium titanium oxide, a barium titanium oxide, a strontium titanium oxide, a lithium oxide, an aluminum oxide, a lead scandium tantalum oxide, or a lead zinc niobate. In some implementations, the ferroelectric material may include a Hf compound. The Hf compound may be, e.g., an Hf-based oxide. The Hf-based oxide may further include at least one impurity selected from Zr, Si, Al, Y, Gd, La, Sc, or Sr. The ferroelectric material may include, e.g., HfO₂, HfZnO, HfSiO, HfSiON, HfTaO, HfTiO, HfZrO, or a combination thereof. In some implementations, the antiferroelectric material may include at least one selected from a hafnium oxide (HfO₂), a zirconium oxide (ZrO₂), a hafnium-zirconium oxide (HfₓZr₁₋ₓO₂, where 0<x<1), PbZrO₃, PbHfO₃, and a combination thereof. Additionally, the dielectric layer 320 may have a multilayer structure. Additionally, a conductive layer 350 (shown in FIG. 13) may be positioned between the dielectric layer 320 and the first electrode 310 or the second electrode 330. Various examples of the dielectric layer 320 will be described later with reference to the drawings.

Referring to FIG. 1 and FIG. 2, a plurality of second electrodes 330 may be positioned to extend in a direction that is parallel to the substrate 110. Referring to FIG. 1, a plurality of second electrodes 330 may be positioned to extend in the second direction DR2 and to be spaced apart from each other in the first direction DR1. Additionally, referring to FIG. 2, the second electrodes 330 may be positioned spaced apart in the third direction DR3. An interlayer insulating layer 130 may be positioned between each of the second electrodes 330. The interlayer insulating layer 130 may include an insulating material. The interlayer insulating layer 130 may include a silicon oxide and/or a silicon nitride, but the scope of the present disclosure is not limited thereto.

Each second electrode 330, the dielectric layer 320, and the first electrode 310 may constitute a capacitor 300. For example, one second electrode 330, the dielectric layer 320, and the first electrode 310 spaced apart in the third direction DR3 may constitute one capacitor 300, and the semiconductor device may have a plurality of capacitors 300 stacked in the third direction DR3 as illustrated in FIG. 2. These capacitors 300 may constitute a data storage.

The second electrode 330 may include a conductive material. The second electrode 330 may include, e.g., at least one of a metal material, a conductive metal nitride, or a doped semiconductor material.

In some implementations, the first electrode 310 and the second electrode 330 may include a same material, but the present disclosure is not limited thereto. For example, the first electrode 310 and the second electrode 330 may include different materials. For example, the first electrode 310 and the second electrode 330 may include materials having different work functions. When the first electrode 310 and the second electrode 330 include materials having different work functions and the dielectric layer 320 includes a ferroelectric material, a hysteresis curve of the dielectric layer 320 may shift. In this case, a write voltage and a read voltage of a ferroelectric memory may be set differently, and the read voltage may be lowered.

Referring to FIG. 2, thicknesses of the second electrodes 330 positioned spaced apart in the third direction DR3 may be different. As illustrated in FIG. 2, a thickness H1 of the second electrode 330 nearest to the substrate 110 may be greater than a thickness H2 of the second electrode 330 in the layer directly above.

In FIG. 2, the second electrode 330 of a 10^{th} layer is illustrated as being uppermost in the third direction DR3. However, this is an example for better understanding and ease of description, and a number of stacked second electrodes 330 may be different from ten.

In some implementations, when a thickness of the second electrode 330 positioned in an n^{th} layer is Hn, Hn may decrease as n increases. For example, as illustrated in FIG. 2, thicknesses of the second electrodes 330 positioned in each layer may have a relationship H1>H2>H3>H4>H5>H6>H7>H8>H9>H10. In FIG. 2, only 10 layers are illustrated for convenience of description, but even when the second electrode 330 is stacked in N layers, a thickness of each second electrode 330 may follow a relationship H1>H2>H3>H4 . . . >Hn. For example, the thickness of the second electrode 330 may become thinner as it moves away from the substrate 110.

This configuration can improve capacitance differences and sensing margins of each capacitor due to an area of the first electrode 310 becoming narrower as it gets closer to the substrate 110 as described above. For example, the difference in thicknesses of the second electrodes 330 can compensate for the effect of the area of the first electrode 310 changing in the third direction DR3.

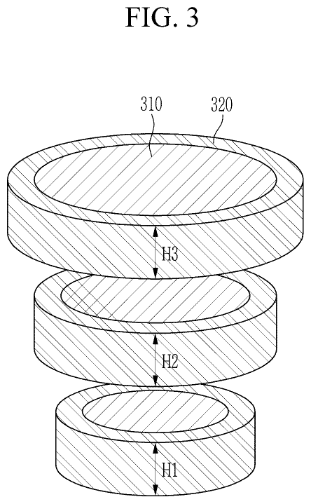

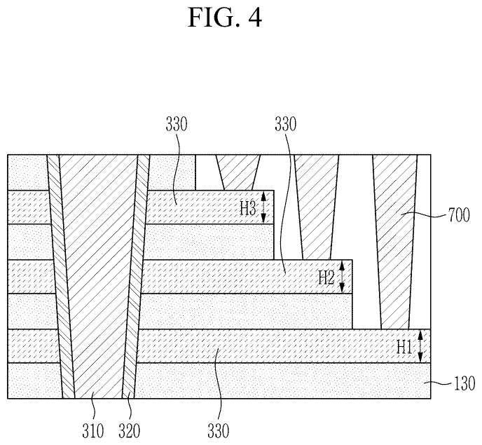

Hereinafter, an example of an effect of the semiconductor device will be described in detail. FIG. 3 and FIG. 4 illustrate areas of individual capacitors in a semiconductor device where a thickness of the second electrodes 330 is uniform. FIG. 3 illustrates a three-dimensional view of the first electrode 310 and the dielectric layer 320 in each capacitor, while FIG. 4 illustrates a cross-sectional view of the capacitor depicted in FIG. 3, including the first electrode 310, the dielectric layer 320, and the second electrode 330.

Referring to FIGS. 3 and 4, as described above, in a hole formation process for forming the first electrode 310, an area of the first electrode 310 may be formed differently for each region due to etching distribution. Accordingly, when the thickness of the second electrode 330 is formed to be the same (H1=H2=H3), an area of the capacitor may vary for each layer, which may cause a difference in sensing margin. In addition, as shown in FIG. 4, a length of the second electrode 330 connected to a contact electrode 700 is different for each layer, so RC delay may occur.

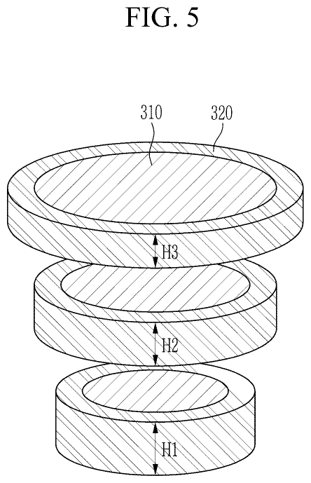

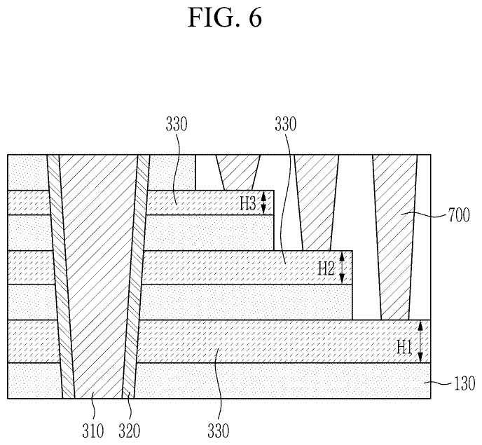

FIG. 5 and FIG. 6 illustrate areas of individual capacitors in a semiconductor device where the thickness of the second electrode 330 varies by region, e.g., as described with respect to FIG. 2. FIG. 5 illustrates a three-dimensional view of the first electrode 310 and the dielectric layer 320 in each capacitor, while FIG. 6 illustrates a cross-sectional view including the first electrode 310, the dielectric layer 320, and the second electrode 330.

Referring to FIG. 5 and FIG. 6, the thickness of the second electrode 330 may vary by region. For example, the thickness H1 of the second electrode 330 may be the thickest in a capacitor where the area of the first electrode 310 is the smallest, and a thickness H3 of the second electrode 330 may be the thinnest in a capacitor where the area of the first electrode 310 is the largest. Accordingly, a reduction in the capacitor area caused by the small area of the first electrode 310 may be compensated for by increasing the thickness of the second electrode 330. Therefore, areas of the capacitors positioned in each layer may be similar, minimizing the difference in sensing margins. In addition, as illustrated in FIG. 6, although the length of the second electrode 330 connected to the contact electrode 700 is different for each layer, resistance differences caused by these length variations may be compensated by forming the thickness of the second electrode 330 differently, thereby reducing RC delay differences between the layers.

In FIG. 2, the thickness of the second electrodes 330 positioned in each layer is illustrated to be entirely different for each second electrode 330, but in some implementations, the thickness of the second electrodes 330 may vary by specific groups, while being uniform within a same group.

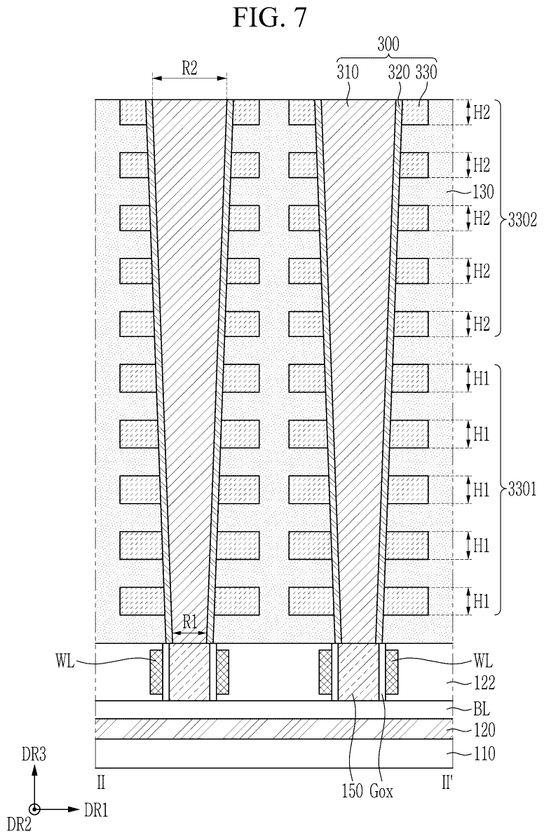

For example, FIG. 7 illustrates a region corresponding to that of FIG. 2 in another example of a semiconductor device. Referring to FIG. 7, the thickness of the second electrode 330 may be different for each group. Referring to FIG. 7, the second electrodes 330 positioned in a first group 3301 may have a first thickness H1, and the second electrodes 330 included in a second group 3302 may have a second thickness H2. In FIG. 7, a configuration is illustrated in which five second electrodes 330 are included in one group, but this is merely an example, and a number of second electrodes 330 included in a group may vary. In addition, in FIG. 7, for convenience of description, ten second electrodes 330 and two groups are illustrated, but this is merely an example, and the number of second electrodes 330 to be stacked and the number of groups may vary.

In some implementations, as shown in FIG. 7, the thickness H1 of the second electrode 330 of the first group 3301, which is positioned closest to the substrate 110, may be greater than the thickness H2 of the second electrode 330 of the second group 3302, which is positioned further away from the substrate 110. Accordingly, as in the example of FIG. 2, a difference in sensing margin due to a difference in the area of the first electrode 310 per region may be compensated for. In the example of FIG. 2, a process is used to form the second electrode 330 positioned in each layer with different thicknesses, but in the example of FIG. 7, the process may be simplified compared to the example of FIG. 2 by dividing the second electrode 330 into groups and forming them with different thicknesses.

In addition, in FIGS. 2 and 7, the first electrode 310 is illustrated to have a cylindrical shape extending in the third direction DR3, with the dielectric layer 320 positioned along a periphery of the first electrode 310, but shapes of the first electrode 310 and the dielectric layer 320 may vary.

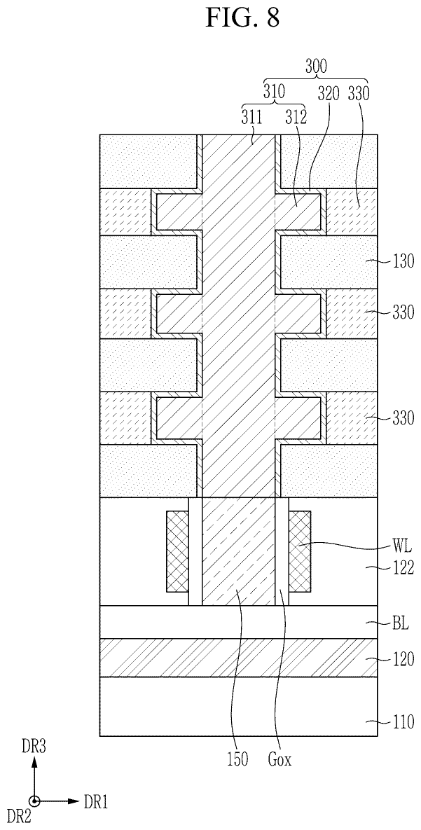

For example, FIG. 8 illustrates a portion indicated by A in FIG. 2 in another example of a semiconductor device. Referring to FIG. 8, the semiconductor device may include the first electrode 310 having a first portion 311 extending in the third direction DR3 and a second portion 312 protruding in the first direction DR1. In this case, the second portion 312 may be positioned adjacent to the second electrode 330. For example, the second portion 312 may be positioned parallel to the second electrode 330 in the first direction DR1, and the second portion 312 may not be positioned in a portion where the second electrode 330 is not positioned. Additionally, the dielectric layer 320 may be positioned along an edge of the first electrode 310. Accordingly, in the cross-section shown in FIG. 8, the dielectric layer 320 may include a protrusion protruding in the first direction DR1. For semiconductor devices having this shape, capacitance of the capacitor may be increased by increasing an area of the capacitor.

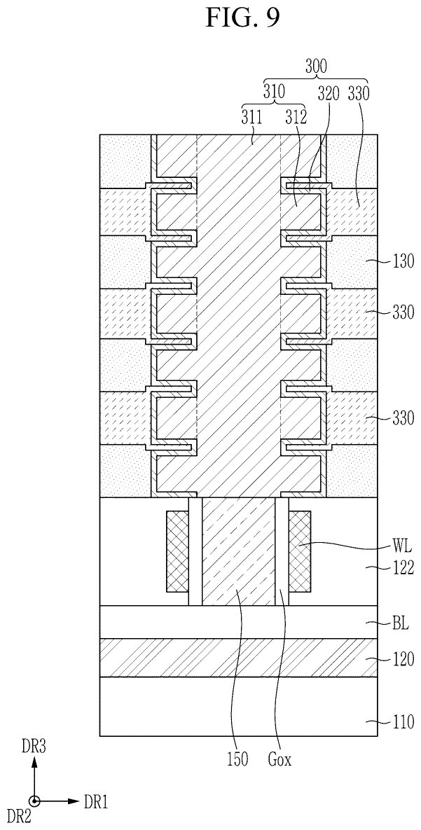

FIG. 9 illustrates a cross-section corresponding to that of FIG. 8 for another example of a semiconductor device. Referring to FIG. 9, the semiconductor device is similar or identical to that of FIG. 8 except that the first electrode 310 includes more second portions 312 than in FIG. 8. Below, detailed descriptions of the same components will be omitted. Referring to FIG. 8, the first electrode 310 may have the first portion 311 extending in the third direction DR3 and the second portion 312 protruding in the first direction DR1. Referring to FIG. 9, the second portion 312 may also be positioned in a portion that is adjacent to the second electrode 330 in the first direction DR1 and in a portion that is adjacent to the interlayer insulating layer 130 in the first direction DR1. In the example of FIG. 8, the second portion 312 is positioned on a same layer as that of the second electrode 330, but in the example of FIG. 9, the second portion 312 may be positioned on the same layer as that of the second electrode 330 and also on the same layer as that of the interlayer insulating layer 130. For example, the semiconductor device of FIG. 9 may include more second portions 312 (e.g., per capacitor) than in the example of FIG. 8. In the example of FIG. 9, the dielectric layer 320 may be positioned along an edge of the first electrode 310. Accordingly, in the cross-section illustrated in FIG. 9, the dielectric layer 320 may include more protrusions (e.g., per capacitor) than in the example of FIG. 8. For semiconductor devices having this and similar shapes, a capacitance of the capacitor may be increased by increasing an area of the capacitor.

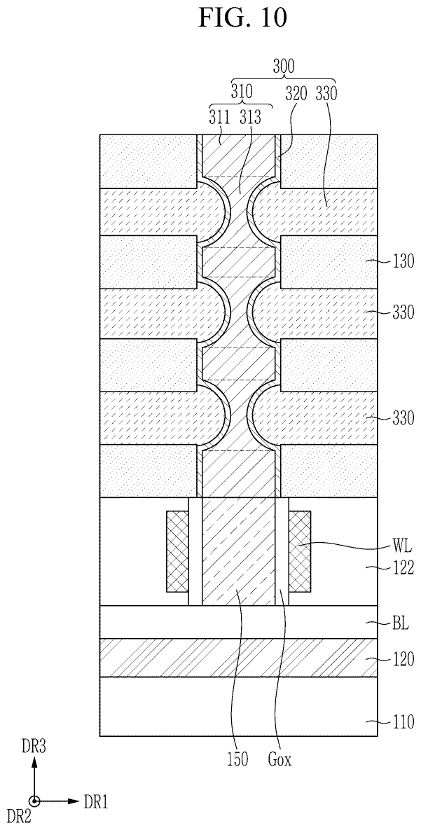

FIG. 10 illustrates a cross-section corresponding to that of FIG. 8 for another example of a semiconductor device. Referring to FIG. 10, the semiconductor device may include the first electrode 310 having a vertical portion 311 and a recessed portion 313 in which a width of the first electrode 310 changes in the third direction DR3 (e.g., narrows).

Each recessed portion 313 may be positioned parallel to or overlapping the second electrode 330 in the first direction DR1. The second electrode 330 may be positioned to extend in the first direction DR1 in an area where the recessed portion 313 of the first electrode 310 is positioned. As illustrated in FIG. 10, the recessed portion 313 may include a curved surface. The dielectric layer 320 may also be positioned along an edge of the first electrode 310. Compared to FIG. 2, the dielectric layer 320 may be formed along a surface of the recessed portion 313 to increase the area of the capacitor and increase the capacitance of the capacitor. In the examples of FIGS. 8 and 9, in some implementations, a planar area of the first electrode 310 increases along with the increase in the capacitance of the capacitor. In the example of FIG. 10, in some implementations, the capacitance of the capacitor may be increased without increasing the planar area of the first electrode 310.

In the foregoing description, a capacitor was briefly described as having a configuration including the first electrode 310, the dielectric layer 320, and the second electrode 330, but a structure of the capacitor may be different in some implementations.

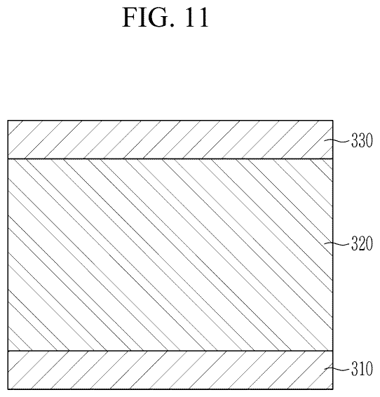

FIG. 11 illustrates a schematic diagram (e.g., a cross-sectional diagram) showing the first electrode 310, the dielectric layer 320, and the second electrode 330 of an example of a capacitor. Referring to FIG. 11, the first electrode 310 and the second electrode 330 may include a same material, or may include materials with different work functions. When the first electrode 310 and the second electrode 330 include materials having different work functions and the dielectric layer 320 includes a ferroelectric material, a hysteresis curve of the dielectric layer 320 may shift. In this case, a write voltage and a read voltage of a ferroelectric memory may be set differently, and the read voltage may be lowered.

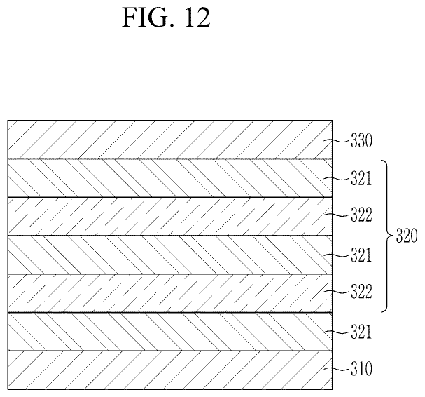

FIG. 12 illustrates a cross-section corresponding to that of FIG. 11 for another example of a capacitor. Referring to FIG. 12, the dielectric layer 320 may have a multilayer structure. Referring to FIG. 12, the dielectric layer 320 may have a structure in which a first layer 321 and a second layer 322 are alternately stacked. For example, the first layer 321 may include a ferroelectric material, and the second layer 322 may include a high-dielectric constant material.

FIG. 13 illustrates a cross-section corresponding to that of FIG. 11 for another example of a capacitor. Referring to FIG. 13, the capacitor may include a conductive layer 350 positioned between the dielectric layer 320 and the second electrode 330. The conductive layer 350 may include, e.g., IGZO, but the present disclosure is not limited thereto. In this way, when the conductive layer 350 is positioned on a first side of the dielectric layer 320 and the dielectric layer 320 includes a ferroelectric material, a hysteresis curve of the dielectric layer 320 may shift. In this case, a write voltage and a read voltage of a ferroelectric memory may be set differently, and the read voltage may be lowered.

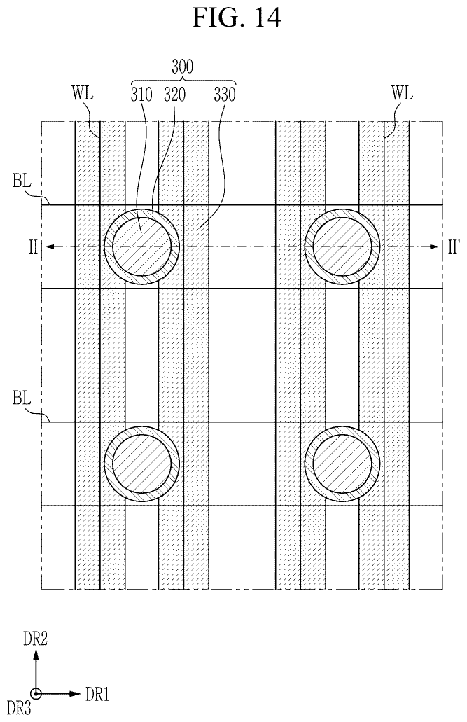

In some implementations of the semiconductor device described with respect to FIG. 1 and FIG. 2, the second electrode 330 surrounding the first electrode 310 is not separated, but in some implementations according to the present disclosure, the second electrode 330 positioned adjacent to the first electrode 310 may be positioned separately. For example, FIG. 14 illustrates a plan view corresponding to that of FIG. 1 for another example of a semiconductor device. Referring to FIG. 14, the semiconductor device is similar or identical to the example of FIG. 1 except that the first electrode 310 and the adjacent second electrode 330 are separated in the first direction DR1. Detailed descriptions of the same components will be omitted.

Additionally, although configurations in which the dielectric layer 320 is positioned along an edge of the first electrode 310 were previously described, in some implementations, the dielectric layer 320 may be positioned along an edge of the second electrode 330.

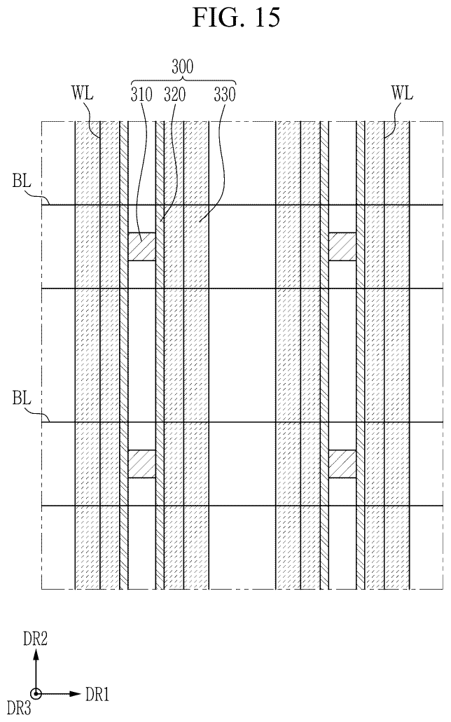

In addition, configurations in which the planar shape of the first electrode 310 is circular were previously described, this is merely an example, and the planar shape of the first electrode 310 may be quadrangular or another shape. For example, FIG. 15 illustrates a plan view corresponding to that of FIG. 1 for another example of a semiconductor device. Referring to FIG. 15, the semiconductor device is similar or identical to the example of FIG. 1 except that the planar shape of the first electrode 310 is quadrangular, the second electrode 330 adjacent to the first electrode 310 is separated therefrom in the first direction DR1, and the dielectric layer 320 is positioned along a first side surface of the second electrode 330. Detailed descriptions of the same components will be omitted.

Hereinafter, an example of a manufacturing method for a semiconductor device will be described. Below, the manufacturing method for a semiconductor device having a shape as illustrated in FIG. 9 will be described, but this is merely an example, and the present disclosure is not limited thereto. For example, it will be understood that aspects of the manufacturing method are applicable to other examples of semiconductor devices described herein.

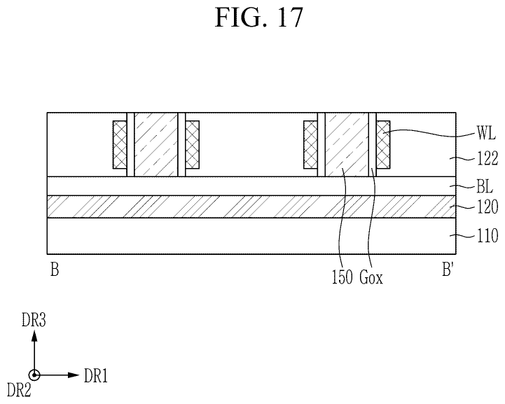

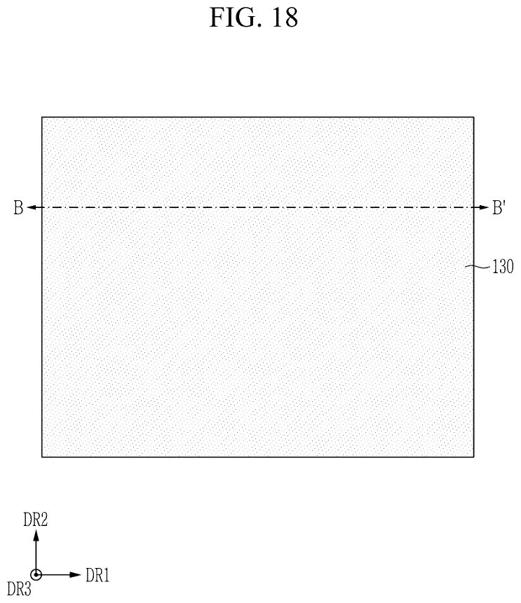

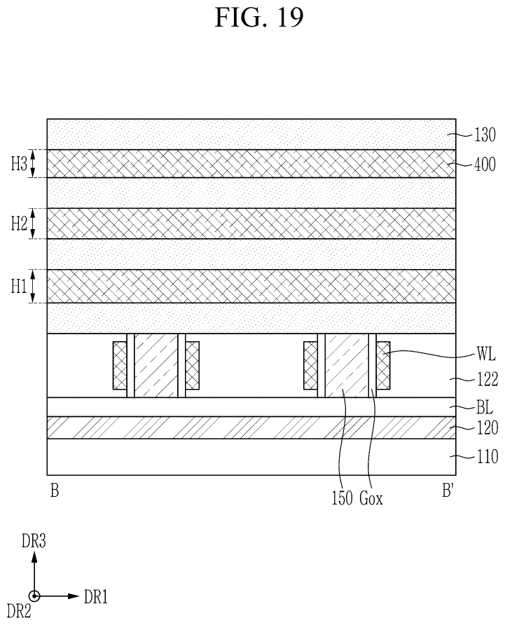

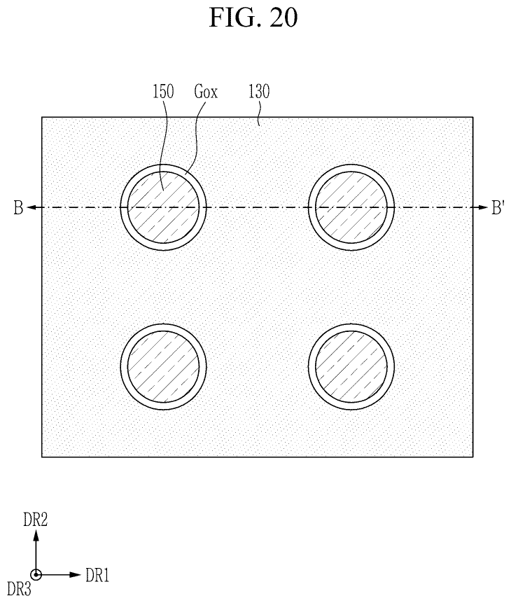

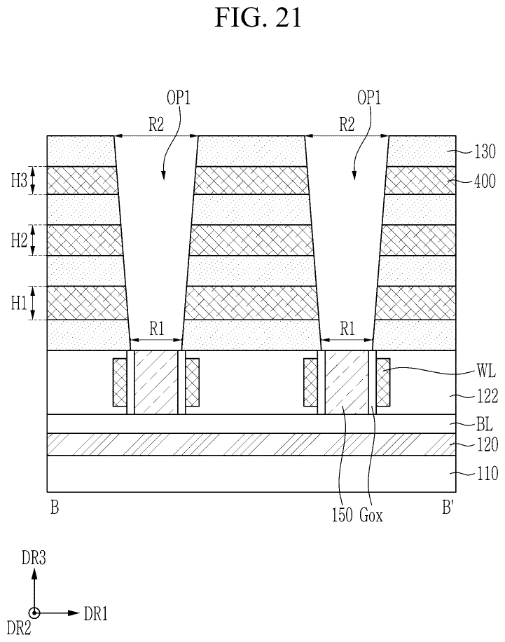

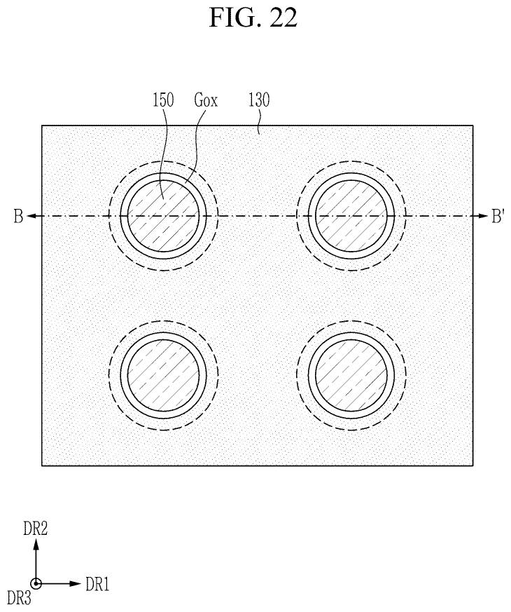

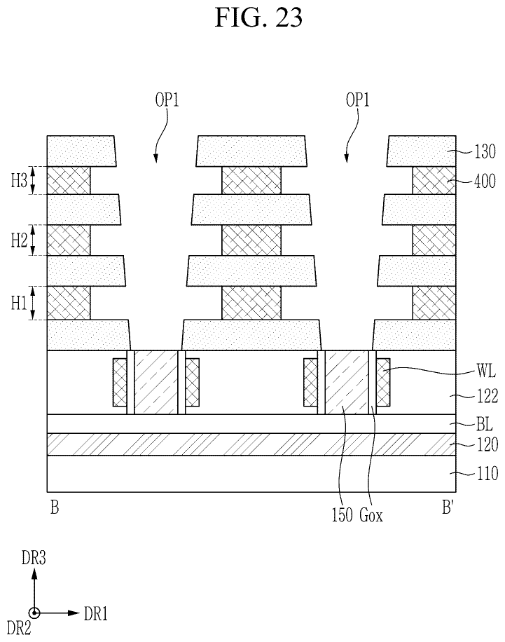

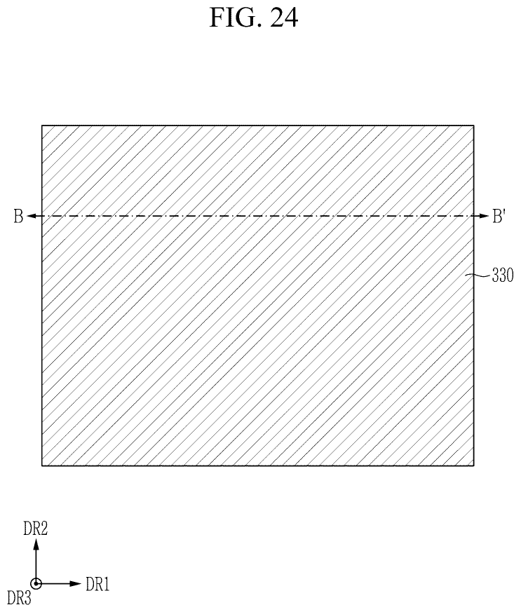

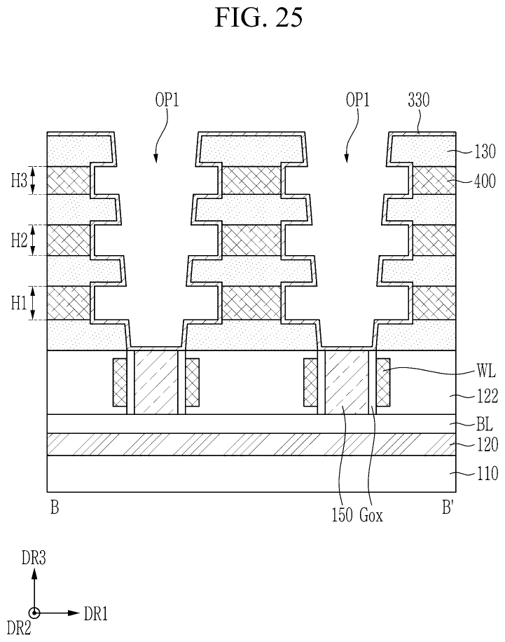

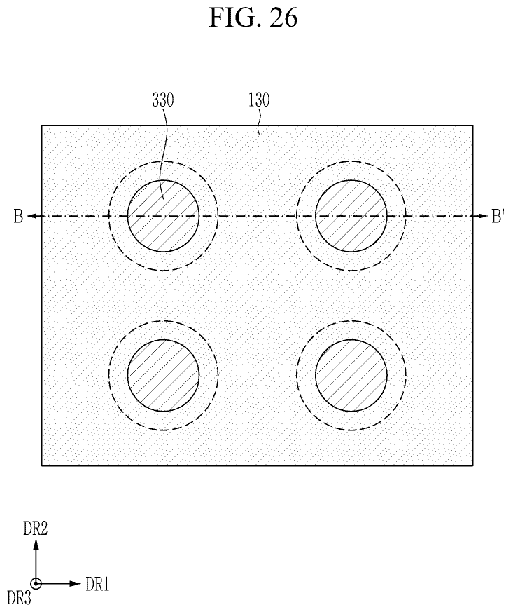

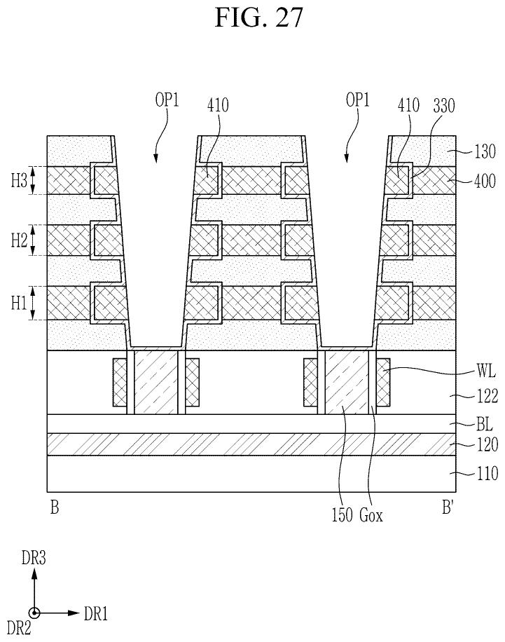

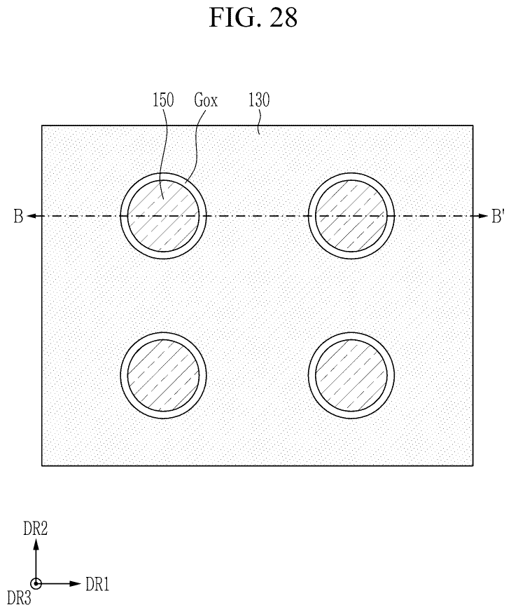

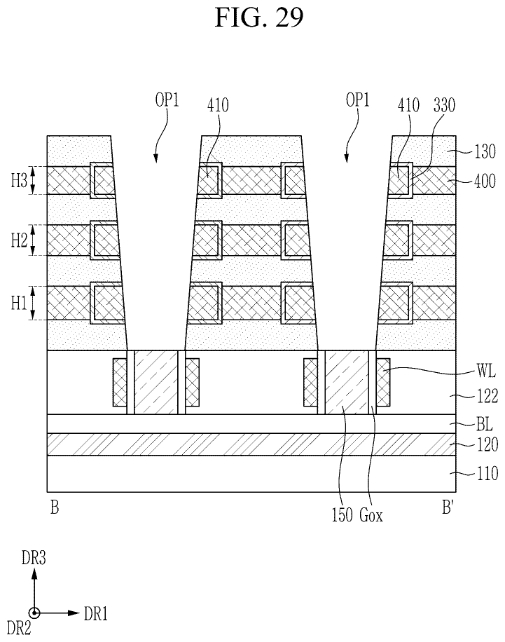

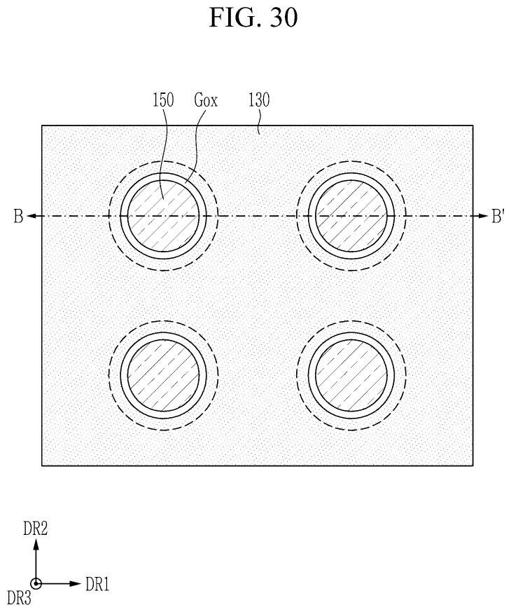

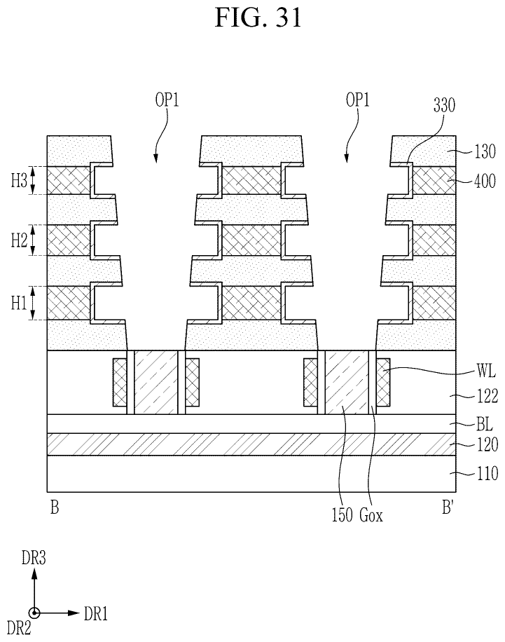

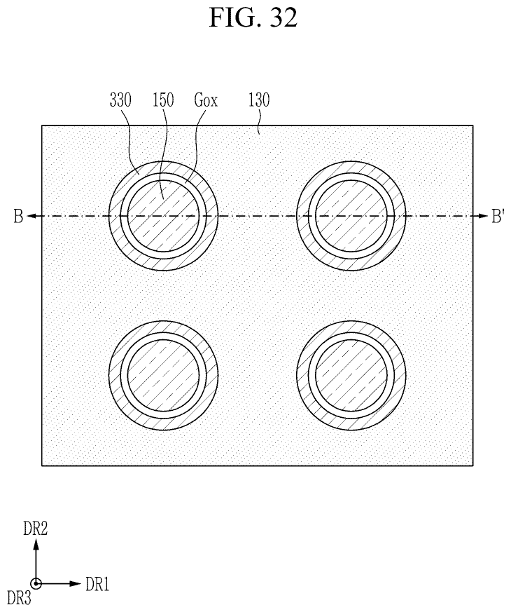

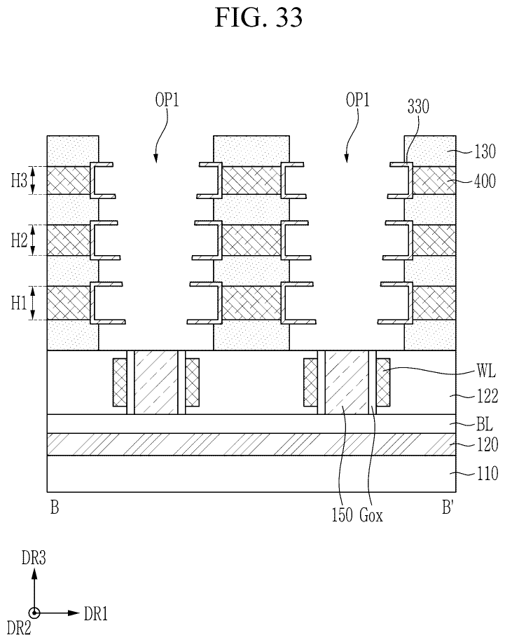

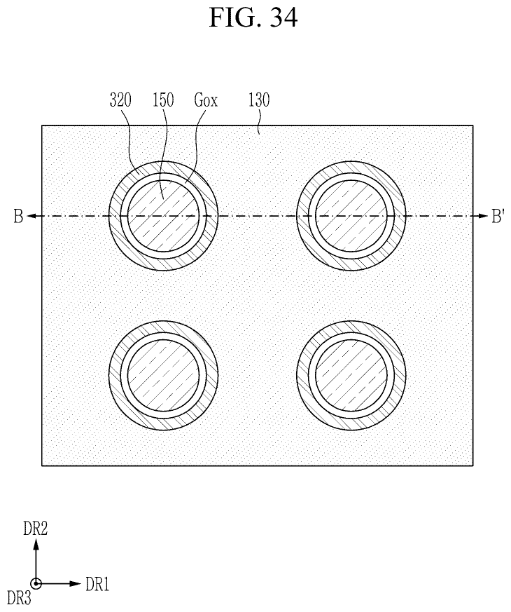

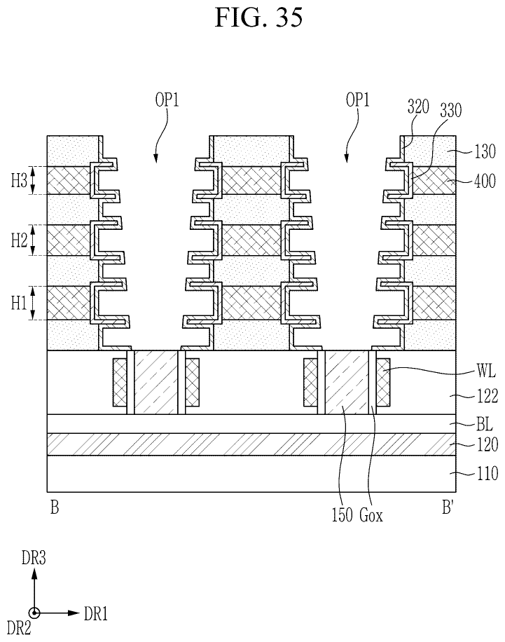

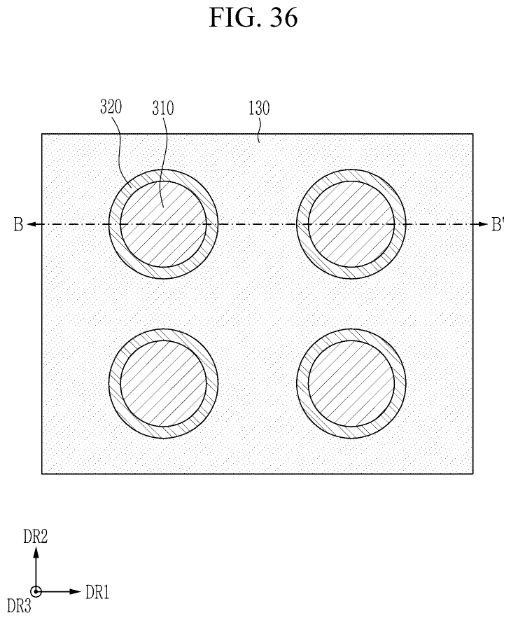

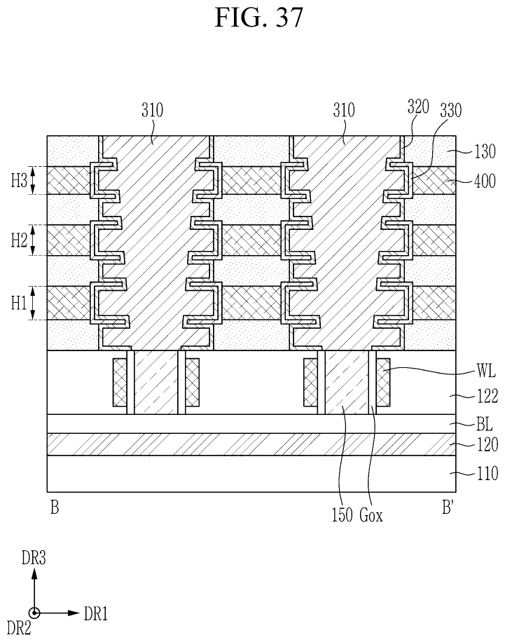

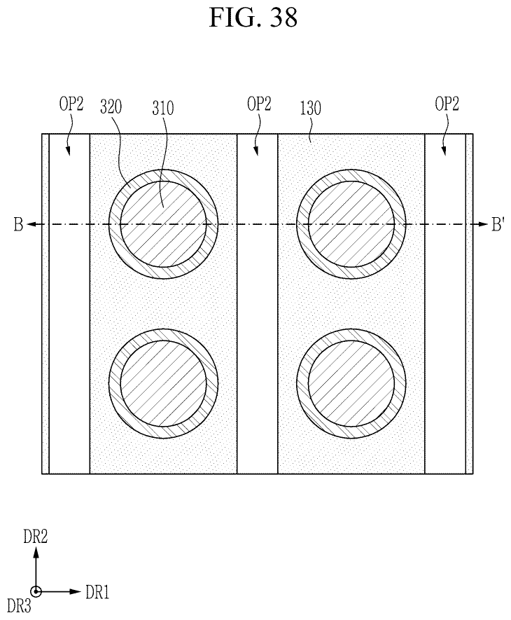

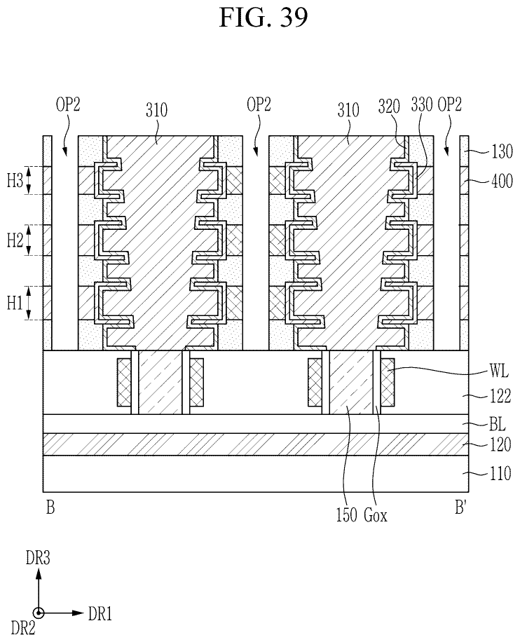

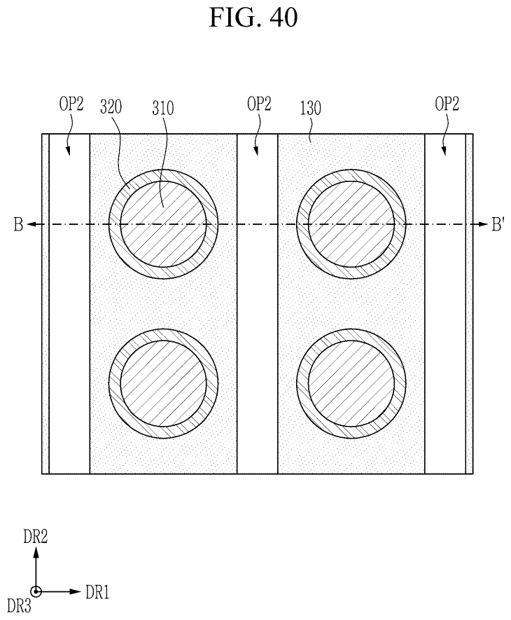

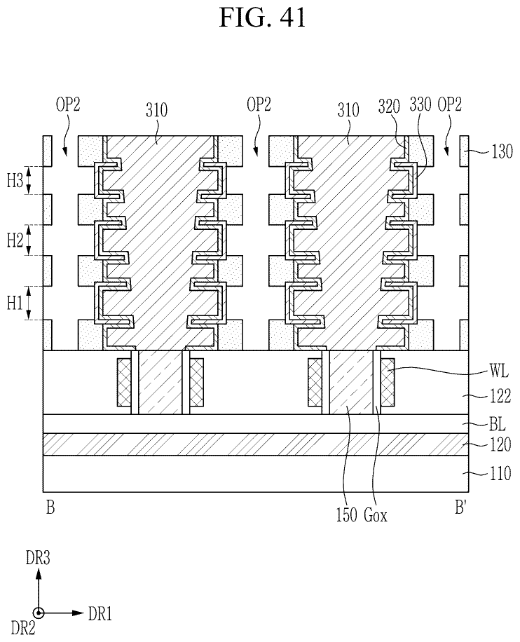

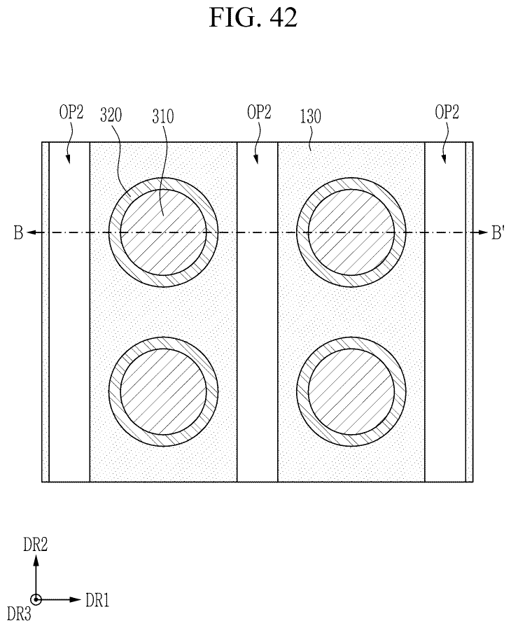

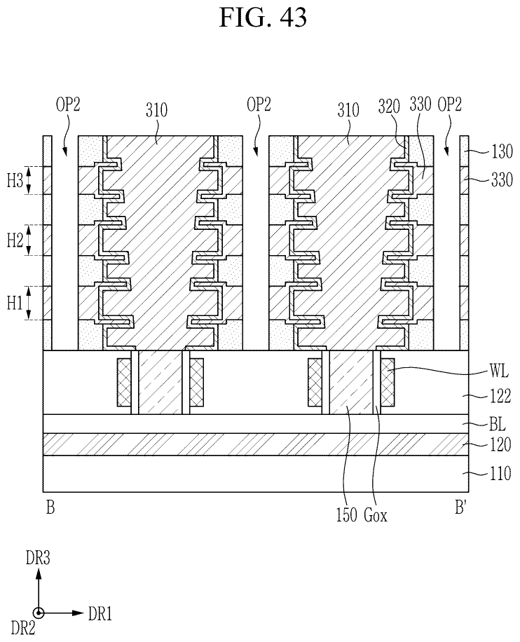

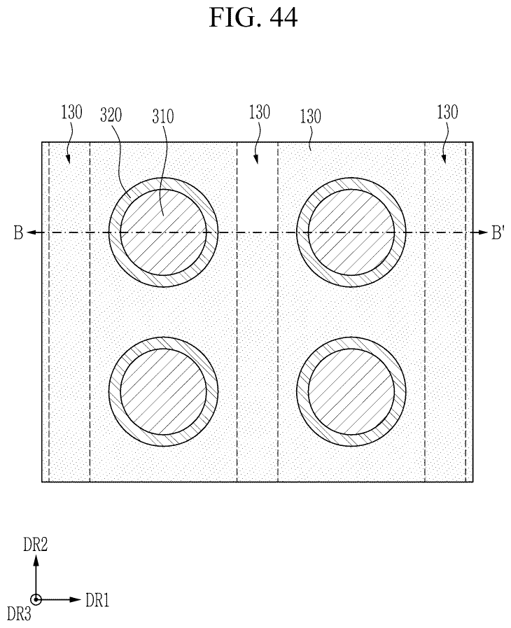

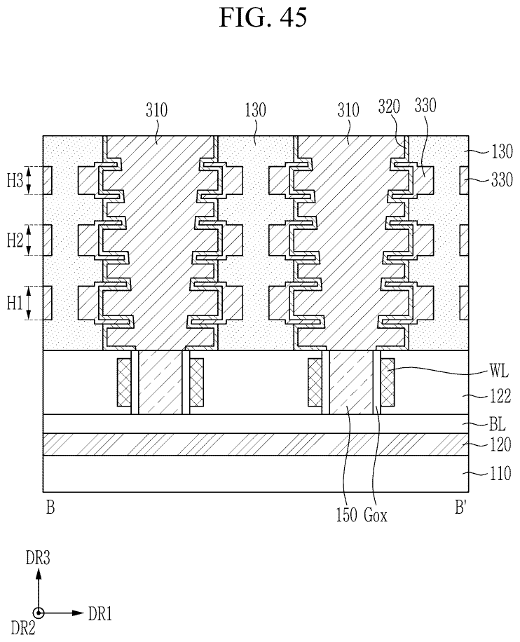

FIG. 16 to FIG. 45 are process diagrams illustrating an example of a manufacturing process for a semiconductor device. FIG. 16, FIG. 18, FIG. 20, FIG. 22, FIG. 24, FIG. 26, FIG. 28, FIG. 30, FIG. 32, FIG. 34, FIG. 36, FIG. 38, FIG. 40, FIG. 42, and FIG. 44 are plan views, and FIG. 17, FIG. 19, FIG. 21, FIG. 23, FIG. 25, FIG. 27, FIG. 29, FIG. 31, FIG. 33, FIG. 35, FIG. 37, FIG. 39, FIG. 41, FIG. 43, and FIG. 45 are cross-sectional views taken along a B-B′ line of FIG. 16, FIG. 18, FIG. 20, FIG. 22, FIG. 24, FIG. 26, FIG. 28, FIG. 30, FIG. 32, FIG. 34, FIG. 36, FIG. 38, FIG. 40, FIG. 42, and FIG. 44, respectively.

Referring to FIGS. 16 and 17, first, the bit line BL extending along the first direction DR1 and the word line WL extending in the second direction DR2 intersecting the bit line BL may be formed on a substrate 110. A first insulating layer 120 may be positioned between the bit line BL and the substrate 110, and a second insulating layer 122 may be positioned between the bit line BL and the word line WL. A semiconductor pattern 150 may be formed at an intersection of the bit line BL and the word line WL. The semiconductor pattern 150 may be positioned surrounded by the word line WL, and the gate insulating layer Gox may be positioned between the semiconductor pattern 150 and the word line WL. Descriptions of the substrate 110, the bit line BL, the word line WL, the semiconductor pattern 150, gate insulating layer Gox, the first insulating layer 120, and the second insulating layer 122 may be the same as those provided above, and are therefore omitted here.

Next, referring to FIG. 18 and FIG. 19, an interlayer insulating layer 130 and a sacrificial layer 400 may be alternately stacked. The interlayer insulating layer 130 may include a silicon oxide and/or a silicon nitride, but the present disclosure is not limited thereto. The sacrificial layer 400 and the interlayer insulating layer 130 may include different materials. The sacrificial layer 400 and the interlayer insulating layer 130 may include a material having an etching selectivity, so the sacrificial layer 400 may be selectively etched in a subsequent process.

The sacrificial layer 400 may be a region where the second electrode 330 is to be subsequently formed, and a thickness of the sacrificial layer 400 may vary between layers. As illustrated in FIG. 19, the thickness H1 of the sacrificial layer 400 positioned in the first layer closest to the substrate 110 may be the thickest, and the thickness of the sacrificial layer 400 may become thinner as it moves away from the substrate 110. FIG. 19 illustrates a three-layer sacrificial layer 400 for convenience of illustration, and the thickness of the sacrificial layer 400 in FIG. 19 may be such that H1>H2>H3. In some implementations, when the sacrificial layer 400 is stacked into N layers, the thickness of each sacrificial layer may be such that H1>H2>H3 . . . >HN. However, this is merely an example, and, for example, in some implementations, the sacrificial layer may include multiple groups, and the thickness of the sacrificial layer may be different for each group, as described above. casein some implementations (e.g., even when multiple groups having a common thickness are included), the thickness of the sacrificial layer included in the group positioned closest to the substrate 110 may be the thickest, and the thickness of the sacrificial layer included in the group positioned farthest from the substrate 110 may be the thinnest.

Next, referring to FIG. 20 and FIG. 21, a first hole OP1 may be formed to extend through a stack of the interlayer insulating layer 130 and the sacrificial layer 400. The first hole OP1 may be formed to overlap the semiconductor pattern 150 in the third direction DR3, and by forming the first hole OP1, the stack of the interlayer insulating layer 130 and the sacrificial layer 400 positioned on an upper surface of the semiconductor pattern 150 may be removed, thereby exposing the semiconductor pattern 150. As previously described, during the formation process of the first hole OP1, an etching process may result in a difference between a diameter R2 at an upper surface farther from the substrate 110 and a diameter R1 at a lower surface adjacent to the substrate 110. For example, the diameter R2 at the upper surface furthest from the substrate 110 may be greater than the diameter R1 at the lower surface adjacent to the substrate 110.

Next, referring to FIG. 22 and FIG. 23 below, a portion of the sacrificial layer 400 may be etched. In FIG. 22, the etched sacrificial layer 400 is illustrated with dashed lines, showing a recessed portion inward into the interlayer insulating layer 130. As illustrated in FIG. 23, a portion of the sacrificial layer 400 may be etched to form a void space between the interlayer insulating layers 130. In this case, etching may be performed using an etchant having an etching selectivity to the sacrificial layer 400. Accordingly, the interlayer insulating layer 130 may not be etched at this operation.

Next, referring to FIG. 24 and FIG. 25, the second electrode 330 may be formed. The second electrode 330 may be positioned on a bottom surface and a side surface of the first hole OP1, and an upper surface of the stack of the interlayer insulating layer 130 and the sacrificial layer 400. As illustrated in FIG. 25, side surfaces of the interlayer insulating layer 130 and the sacrificial layer 400 may be covered with the second electrode 330. The second electrode 330 may include a conductive material. The second electrode 330 may include, e.g., at least one of a metal material, a conductive metal nitride, or a doped semiconductor material.

Next, referring to FIGS. 26 and 27, the second electrode 330, which was positioned on an uppermost surface of the stack of the interlayer insulating layer 130 and the sacrificial layer 400, is removed, and a sacrificial pattern 410 is formed in an empty space between the interlayer insulating layers 130. The sacrificial pattern 410 may be formed to fill a space where a portion of the sacrificial layer 400 was previously etched. The sacrificial pattern 410 may include an insulating material. For example, the sacrificial pattern 410 may include a silicon nitride or a silicon oxide. As illustrated in FIG. 27, by forming the sacrificial pattern 410, a portion of the second electrode 330 may be covered with the sacrificial pattern 410.

Next, referring to FIGS. 28 and 29, the second electrode 330 positioned on the side surface and the bottom surface of the hole OP1 may be removed. However, the second electrode 330 formed in the space between the interlayer insulating layers 130 may be covered with the sacrificial pattern 410, and may not be removed at this operation. Accordingly, as illustrated in FIG. 29, the second electrode 330 may be divided into multiple portions in the first direction DR1 and the third direction DR3. This may then be used to constitute each capacitor.

Next, referring to FIGS. 30 and 31, the sacrificial pattern 410 may be removed. In FIG. 30, a region where the sacrificial pattern 410 is removed and an empty space is formed is shown by a dotted line.

Next, referring to FIGS. 32 and 33, the interlayer insulating layer 130 may be partially etched. In this case, referring to FIG. 33, the second electrode 330 formed previously may be exposed by etching the interlayer insulating layer 130. By etching the interlayer insulating layer 130 in this operation, an edge of the interlayer insulating layer 130 and an edge of the sacrificial layer 400 may be aligned.

Next, referring to FIGS. 34 and 35, the dielectric layer 320 may be formed. The dielectric layer 320 may include at least one of a high-dielectric material, a ferroelectric material, or an antiferroelectric material. The dielectric layer 320 may be formed along the side surface of the hole OP1. As illustrated in FIG. 34, the dielectric layer 320 may be formed to cover the side surface of the interlayer insulating layer 130 and the second electrode 330. In the previous operation, the second electrode 330 may include a portion protruding in the first direction DR1, and the dielectric layer 320 may also be formed to cover a front surface of the protruding second electrode 330.

Next, referring to FIGS. 36 and 37, the first electrode 310 may be formed inside the hole OP1. The first electrode 310 may be formed to completely fill an inside of the hole OP1. The first electrode 310 may include a conductive material. The first electrode 310 may include, e.g., at least one of a metal material, a conductive metal nitride, and a doped semiconductor material.

Next, referring to FIG. 38 and FIG. 39, a second hole OP2 may be formed to extend through a stack of the interlayer insulating layer 130 and the sacrificial layer 400. In this case, the second hole OP2 may be formed in a region that does not overlap the semiconductor pattern 150. Side surfaces of the interlayer insulating layer 130 and the sacrificial layer 400 may be exposed by forming the second hole OP2.

Next, referring to FIG. 40 and FIG. 41, the sacrificial layer 400 may be removed through the second hole OP2. As described above, the sacrificial layer 400 and the interlayer insulating layer 130 have etching selectivity, so only the sacrificial layer 400 may be selectively removed. Accordingly, an empty space may be formed between the interlayer insulating layers 130 as illustrated in FIG. 41. The second electrode 330 formed in the previous operation may be exposed by removing the sacrificial layer 400.

Referring to FIGS. 42 and 43, a second electrode 330 is formed in the space where the sacrificial layer 400 has been removed. In some implementations, the second electrode 330 formed in this operation includes a same material as that of the second electrode 330 formed in the previous operation, so a boundary with the second electrode 330 formed in the previous operation may not be recognized.

Referring to FIGS. 44 and 45, the second hole OP2 may be filled with a material of the interlayer insulating layer 130. When the material filling the second hole OP2 includes a same material as that of the interlayer insulating layer 130 formed in the previous operation, a boundary with the interlayer insulating layer 130 formed in the previous operation may not be visible. However, this is merely an example, and when the material filling the second hole OP2 is a different material from the interlayer insulating layer 130 material, the boundary may be recognized.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although examples have been described in detail above, the scope of the present disclosure is not limited thereto, and various modifications and improvements made by those skilled in the art also fall within the scope of the present disclosure.

What is claimed is:

1. A semiconductor device comprising:
a substrate;
a bit line and a word line extending in respective intersecting directions on the substrate;
a semiconductor pattern electrically connected to the bit line;
a first electrode extending in a first direction that is perpendicular to a surface of the substrate, wherein the first electrode is electrically connected to the semiconductor pattern;
a plurality of second electrodes spaced apart along the first direction; and
a dielectric layer between the first electrode and the plurality of second electrodes,
wherein the first electrode, the plurality of second electrodes, and the dielectric layer are configured to form a plurality of data storages,
wherein a planar area of the first electrode parallel to the surface of the substrate increases as a distance from the substrate increases,
wherein the plurality of second electrodes include a lower electrode and an upper electrode,
wherein a distance between the upper electrode and the substrate is greater than a distance between the lower electrode and the substrate, and
wherein a thickness of the lower electrode in the first direction is greater than a thickness of the upper electrode in the first direction.

2. The semiconductor device of claim 1, wherein a width of a lower surface of the first electrode in a second direction that is parallel to the surface of the substrate is smaller than a width of an upper surface of the first electrode in the second direction,
wherein a distance between the lower surface of the first electrode and the substrate is less than a distance between the upper surface of the first electrode and the substrate.

3. The semiconductor device of claim 1, wherein the first electrode includes:
a first portion that extends in the first direction; and
a plurality of second portions that protrude from the first portion in a second direction that is parallel to the surface of the substrate,
wherein the dielectric layer extends along the first portion and the second portions.

4. The semiconductor device of claim 3, wherein the plurality of second portions are respectively overlapping with the plurality of second electrodes along the second direction.

5. The semiconductor device of claim 3, wherein:
a first set of the plurality of second portions are respectively overlapping with a set of the plurality of second electrodes along the second direction, and
a second set of the plurality of second portions are non-overlapping with the plurality of second electrodes.

6. The semiconductor device of claim 1, wherein:
the first electrode includes a recessed portion, wherein a planar area of the recessed portion parallel to the surface of the substrate changes as the distance from the substrate increases, and
wherein the recessed portion is positioned adjacent to one second electrode of the plurality of second electrodes.

7. The semiconductor device of claim 1, wherein the first electrode is composed of a first metal,
wherein the plurality of second electrodes is composed of a second metal, and
wherein the first metal and the second metal have different work functions.

8. The semiconductor device of claim 1, comprising a conductive layer positioned between the first electrode and the dielectric layer.

9. The semiconductor device of claim 1, wherein the dielectric layer has a multilayer structure comprising a ferroelectric material and a high-dielectric constant material, wherein the ferroelectric material and the high-dielectric constant material are alternately stacked in the dielectric layer.

10. The semiconductor device of claim 1, wherein the plurality of second electrodes surround the first electrode in a plan view.

11. The semiconductor device of claim 1, wherein each second electrode of the plurality of second electrodes includes:
a first portion, and
a second portion spaced apart from the first portion.

12. A semiconductor device comprising:
a substrate;
a bit line and a word line extending in respective intersecting directions on the substrate;
a semiconductor pattern electrically connected to the bit line;
a first electrode extending in a first direction that is perpendicular to a surface of the substrate;
a plurality of second electrodes spaced apart along the first direction; and
a dielectric layer between the first electrode and the plurality of second electrodes,
wherein the first electrode, the plurality of second electrodes, and the dielectric layer are configured to form a plurality of data storages,
wherein a planar area of the first electrode parallel to the surface of the substrate increases as a distance from the substrate increases,
wherein the plurality of second electrodes includes:
a first group of second electrodes having a first thickness in the first direction, and
a second group of second electrodes having a second thickness in the first direction,
wherein the first thickness is greater than the second thickness, and
wherein the first group of second electrodes is positioned closer to the substrate than the second group.

13. The semiconductor device of claim 12, wherein a width of a lower surface of the first electrode in a second direction that is parallel to the surface of the substrate is smaller than a width of an upper surface of the first electrode in the second direction,
wherein a distance between the lower surface of the first electrode and the substrate is less than a distance between the upper surface of the first electrode and the substrate.

14. The semiconductor device of claim 12, wherein the first electrode includes:
a first portion that extends in the first direction; and
a plurality of second portions that protrude from the first portion in a second direction that is parallel to the surface of the substrate,
wherein the dielectric layer extends along the first portion and the second portions.

15. The semiconductor device of claim 12, wherein:
the first electrode includes a recessed portion, wherein a planar area of the recessed portion parallel to the surface of the substrate changes as the distance from the substrate increases, and
wherein the recessed portion is positioned adjacent to one second electrode of the plurality of second electrodes.

16. The semiconductor device of claim 12, wherein the first electrode is composed of a first metal,
wherein the plurality of second electrodes is composed of a second metal, and
wherein the first metal and the second metal have different work functions.

17. The semiconductor device of claim 12, wherein the dielectric layer has a multilayer structure comprising a ferroelectric material and a high-dielectric constant material, wherein the ferroelectric material and the high-dielectric constant material are alternately stacked in the dielectric layer.

18. A semiconductor device comprising:
a substrate;
a bit line and a word line extending in respective intersecting directions on the substrate;
a semiconductor pattern electrically connected to the bit line;
a first electrode extending in a first direction that is perpendicular to a surface of the substrate;
a plurality of second electrodes spaced apart along the first direction; and
a dielectric layer between the first electrode and the plurality of second electrodes,
wherein the first electrode, the plurality of second electrodes, and the dielectric layer are configured to form a plurality of data storages,
wherein a width of a lower surface of the first electrode in a second direction that is parallel to the surface of the substrate is smaller than a width of an upper surface of the first electrode in the second direction,
wherein a distance between the lower surface of the first electrode and the substrate is less than a distance between the upper surface of the first electrode and the substrate, and
wherein a thickness of a second electrode, among the plurality of second electrodes, that is closest to the substrate, is greater than a thickness of a second electrode, among the plurality of second electrodes, that is positioned farthest from the substrate.

19. The semiconductor device of claim 18, wherein a planar area of the first electrode parallel to the surface of the substrate increases as a distance from the substrate increases.

20. The semiconductor device of claim 18, wherein a respective thickness of each second electrode of the plurality of second electrodes in the first direction increases as a distance of the second electrode from the substrate decreases.
